(19) United States
(12) Patent Application Publication
(10) Pub. No.: US 2009/0173446 A1
(43) Pub. Date: Jul. 9, 2009

(54) SUBSTRATE SUPPORT, SUBSTRATE PROCESSING APPARATUS INCLUDING SUBSTRATE SUPPORT, AND METHOD OF ALIGNING SUBSTRATE

(76) Inventors: Dong-Ju Yang, Seoul (KR); Min-Seok Oh, Yongin-si (KR); Ki-Yeup Lee, Yongin-si (KR); Sang-Gab Kim, Seoul (KR); Shin-Il Choi, Seoul (KR); Hong-Kee Chin, Suwon-si (KR); Yu-Gwang Jeong, Yongin-si (KR); Seung-Ha Choi, Siheung-si (KR); Jae-Ho Jang, Chunan-si (KR)

Correspondence Address: Haynes and Boone, LLP;IP Section, 2323 Victory Avenue, SUITE 700, Dallas, TX, 75219, US

(21) Appl. No.: 12/347,779

(22) Filed: Dec. 31, 2008

(30) Foreign Application Priority Data
Jan. 4, 2008 (KR) 10-2008-0001203

(51) Int. Cl. C23F 1/08; C23C 16/513; H01L 21/68

(52) U.S. Cl. 156/345.51; 118/723 R; 118/500; 414/806

(57) ABSTRACT

The present invention relates to a substrate support that facilitates aligning a substrate and prevents the substrate from being damaged by arc discharge in processing a substrate using plasma, a substrate processing apparatus including the substrate support, and a method of aligning the substrate. A substrate support, which includes a main body on which a substrate is placed and a subsidiary body disposed around the side of the main body and having a slope declining from a position above the main body to the upper side of the main body, is provided, such that it is easy to align the substrate and it is possible to damage due to arc discharge in processing the substrate using plasma.

### CROSS REFERENCE TO RELATED APPLICATION

This application claims the benefit of priority from Korean Patent Application No. 10-2008-0001203 filed on Jan. 4, 2008, in the Korean Intellectual Property Office, the contents of which are incorporated herein by reference in their entirety.

### BACKGROUND OF THE INVENTION

1. Field of the Invention

The present invention relates to a substrate support, a substrate processing apparatus including the substrate support, and a method of aligning the substrate on the substrate support. In particular, the invention relates to a substrate support that facilitates aligning a substrate and prevents the substrate from being damaged by arc discharges during processing of the substrate in a plasma, a substrate processing apparatus including the substrate support, and a method of aligning the substrate on the substrate support.

2. Description of the Related Art

Semiconductor elements and flat panel display elements are formed by depositing a plurality of thin films on a substrate and etching the films. That is, an element with a predetermined thin film pattern is formed by depositing thin films on a predetermined region of a substrate and then removing portions of the thin films by etching with an etching mask.

Processes using plasma have been generally used for depositing or etching thin films. In processes using plasma, high electric power is used to obtain desirable characteristics of the process and the plasma contacts the surface of a substrate where a thin film is deposited or etched, so that an electric voltage may concentrate on a certain region, and cause a localized electric discharge called an arc discharge.

The arc discharge appears when electric potential concentrates on a sharp portion or where dopants are concentrated, on the surface of a substrate or may appear when a substrate is not properly placed on a predetermined position on a lower electrode that supports the substrate and the surface of a portion of the lower electrode is exposed to plasma during dry etching or chemical vapor deposition.

High energy is applied to the portion where the arc discharge appears by concentration of electric potential and the substrate is damaged by the energy. For example,high energy may be applied where partial melting of the substrate occurs or properties of the substrate change. The arc discharge results in defective products by causing damage to the substrate itself or to a variety of element layers on the substrate. In particular, in manufacturing a semiconductor element or a large area flat panel display element, the defects caused by arc discharges reduce yield and increase manufacturing cost.

In particular, in the case of a substrate for a large area flat panel display element, it is difficult to handle the substrate due to the large area, so that separate alignment may be needed to properly place the substrate on a lower electrode. However, when the substrate is not aligned or when the lower electrode is exposed although the substrate is aligned, the substrate may be damaged by arc discharge in a plasma process. Further, when a low-priced substrate is used in place of a high-priced glass substrate to reduce manufacturing cost, dopants are not uniformly distributed as compared with a high-priced substrate, so that the substrate may be more easily damaged by arc discharge generated by concentration of electric potential unless the substrate is placed at a predetermined position on a lower electrode.

### SUMMARY OF THE INVENTION

The present invention provides a substrate support that facilitates aligning a substrate and prevents the substrate from being damaged by arc discharge in processing a substrate using plasma, a substrate processing apparatus including the substrate support, and a method of aligning the substrate.

An aspect of the present invention provides a substrate support including: a main body on which a substrate is placed; and a subsidiary body disposed around the side of the main body and having a slope declining from a position above the main body to the upper side of the main body.

A plurality of gas jet holes is formed through the upper side of the main body and ejection pressure of the gas jet holes at the edge may be larger than that at the center portion of the main body.

Alternatively, a plurality of gas jet holes is formed through the upper side of the main body and the amount of gas ejected per unit area by the gas jet holes at the edge may be larger than the amount of gas ejected per unit area the center portion of the main body.

The distance between the gas jet holes may be smaller at the edge than the center portion of the main body, the diameter of the gas jet holes at the edge may be larger than that of the center portion of the main body, and the number of the gas jet holes per unit area at the edge may be larger than the number of gas jet holes per unit area at the center portion of the main body.

Further, a sliding portion may be formed on the slope and the sliding portion may include grooves formed on the slope and rigid balls inserted in the grooves.

The diameter of the inlet of the groove may be smaller than the diameter of the rigid ball.

Further, at least a part of the subsidiary body may be movable away from or close to the side of the main body.

The subsidiary body may be made of ceramic.

Further, the slope may be curved, and the closer to the main body, the larger the angle of the slope relative to the upper side of the main body.

Another aspect of the present invention provides a substrate processing apparatus including: a chamber into which a substrate is inserted; and a substrate support that is provided in the chamber and includes a main body on which the substrate is placed and a subsidiary body disposed around the side of the main body and having a slope declining from a position above the main body to the upper side of the main body.

The apparatus may further include a plasma generator that generates plasma inside the chamber and the substrate may be a glass or a wafer.

Another aspect of the present invention provides a method of aligning a substrate including: moving a subsidiary body away from a main body having a plurality of gas jet holes, in which the subsidiary body is disposed around the side of the main body and has a slope declining from a position above the main body to the upper side of the main body; placing a substrate onto the main body; ejecting gas onto the substrate placed on the upper side of the main body through the gas jet holes; and moving the subsidiary body to the side of the main body.

In the ejecting of gas, gas ejection pressure at the edge of the main body may be larger than gas ejection pressure at the center portion of the main body.

Further, in the ejecting of gas, the gas ejection pressure may be larger than gravity per unit area exerted in the substrate.

In the ejecting of gas, the amount of gas ejection per unit area at the edge of the main body may be larger than the amount of gas ejection per unit area at the center portion of the main body.

As described above, using a substrate support according to an aspect of the invention, a substrate processing apparatus including the substrate support, and a method for aligning the substrate, it is possible to rapidly place the substrate to the exact position required for best alignment.

Further, since the substrate is rapidly aligned at the exact position, it is possible to prevent damage to the substrate due to arc discharge in processing the substrate using plasma.

Further, since the substrate is rapidly aligned at the exact position and the damage to the substrate is prevented in processes as described above, it is possible to improve manufacturing yield, reduce manufacturing cost, and secure reliability in processing the substrate and the processed substrate as well.

### BRIEF DESCRIPTION OF THE DRAWINGS

The above and other features and advantages of the present invention will become more apparent based on a detailed description of preferred embodiments thereof taken with reference to the attached drawings in which:

FIG. 1 is a schematic cross-sectional view showing a substrate processing apparatus according to an embodiment of the invention;

FIGS. 2A to 2C are schematic cross-sectional views sequentially illustrating a method of aligning of a substrate according to an embodiment of the invention;

FIGS. 3A and 3B are views showing a first modification of a substrate support according to an embodiment and another example of the first modification;

FIG. 4 is a view showing a second modification of a substrate support according to an embodiment of the invention;

FIG. 5 is a view showing a third modification of a substrate support according to an embodiment of the invention;

FIG. 6 is a view showing a fourth modification of a substrate support according to an embodiment of the invention;

FIG. 7 is a view showing a fifth modification of a substrate support according to an embodiment of the invention;

FIG. 8A is a view showing a sixth modification of a substrate support according to an embodiment of the invention;

FIG. 8B is a plan view of the substrate support shown in FIG. 8A, which is formed for a circular substrate; and

FIG. 8C is a plan view of the substrate support shown in FIG. 8A, which is formed for a rectangular substrate.

### DESCRIPTION OF THE PREFERRED EMBODIMENTS

Preferred embodiments of the invention are described hereafter in detail with reference to accompanying drawings. The present invention, however, is not limited to the embodiments described herein, but the embodiments may be modified in a variety of ways, and the embodiments are provided only to fully disclose the invention and inform those skilled in the art of the aspects of the invention.

Though not specifically defined, all of the terms used herein, including scientific terms and technical terms, have the same meanings as those that are generally understood by those skilled in the art. The terms defined in common dictionaries are construed as they have additional meanings corresponding to descriptions herein or in related technical documents, and if not specifically stated, they are not construed as ideal or official meanings.

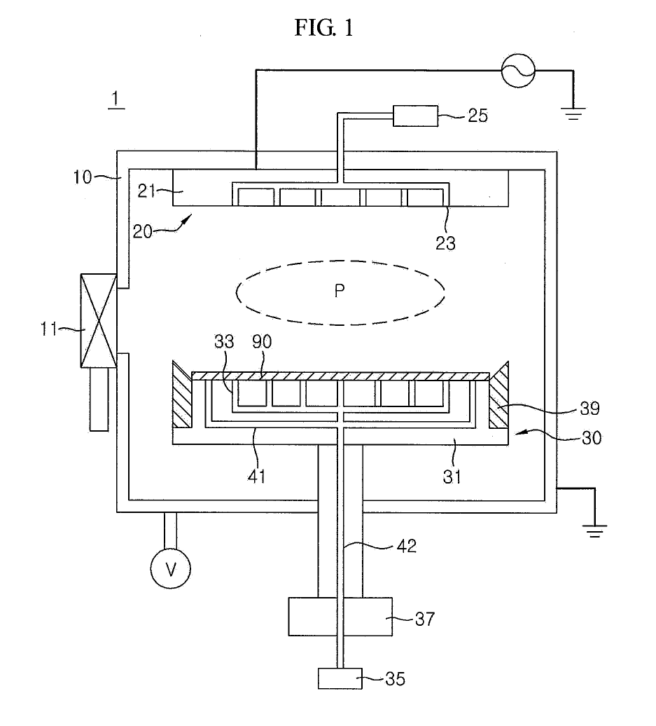

FIG. 1 is a schematic cross-sectional view showing a substrate processing apparatus according to an embodiment of the invention.

Figures that are described herein, including FIG. 1, are schematically shown, and the sizes and shapes of each of the parts are appropriately overdrawn for ease of understanding. The same reference numerals in the figures indicate the same components.

Referring to FIG. 1, a substrate processing apparatus 1 includes a chamber 10 having a space inside, an electrode 20 provided in the chamber 10, and a substrate support 30 disposed apart from the electrode 20 and supporting a substrate 90.

The substrate processing apparatus 1, according to an embodiment of the invention, may be an etching device for plasma etching a predetermined pattern in a film deposited on the surface of the substrate 90, such as a glass substrate, or a semiconductor wafer, or may be a plasma deposition device for depositing a predetermined film onto the surface of the substrate 90.

The chamber 10 may be made of a metal and has a door 11 at a side of the chamber, by which the inside of the chamber 10 can be connected with the outside. Further, the substrate processing apparatus includes a vacuum system V connected with the chamber 10 to provide vacuum inside the chamber 10. The chamber 10 may be grounded through a grounding unit. The door 11 can be actuated manually or automatically and when the door 11 is open the substrate 90 may be inserted into or taken out of the chamber 10. The door 11 is formed such that it can seal the chamber 10 to prevent materials from transferring between the inside and the outside of the chamber 10 when the inside of the chamber 10 is isolated from the outside by closing the door 11.

The electrode 20 is disposed at an upper portion in the chamber 10 and has a body 21 and gas jet holes 23 from which reactive or non-reactive gas is introduced into the chamber 10 through the body 21. Further, the upper electrode 20 may be connected to a source of DC power (not shown) or to a source of high-frequency power, or grounded (not shown). When the electrode 20 is connected to a source of power, and gas is delivered into the chamber 10 through the electrode 20, it is possible to generate plasma inside the chamber 10 by supplying power to the electrode 20. A cooling line may be formed in the electrode 20 to cool the electrode 20 by making a coolant, such as cooling water or gas, flow through the cooling line. The gas jet holes 23 are formed in a shower head type arrangement and they are connected to a gas source 25 to supply reactive or non-reactive gas from the outside of the chamber 10. The flow rate of gas from the gas source 25 into the chamber 10 is controlled by a valve (not shown) or by a flow control unit (not shown) and the gas may flow through a plurality of paths in the body 21 of the electrode 20 and then flow into the chamber 10 from the gas jet holes 23.

The substrate support 30 is disposed apart from and below the electrode 20 in the chamber 10 with the substrate support 30 facing the electrode 20. The substrate support 30 has a main body 31 on which the substrate 90 is placed and a subsidiary body 39 disposed around the sides of the main body 31. The subsidiary body 39 has an upper surface 39a which slopes downwards toward the upper side of the main body 31. The upper surface 39a will hereinafter be referred as the slope 39a. The main body 31 may be connected to a source of DC power (not shown) or to a source of high-frequency power (not shown), or grounded (not shown). Further, the main body 31 has gas jet holes 33 that are open to the upper side of the main body 31 where the substrate 90 is placed, and the gas jet holes 33 are connected to a gas source 35 through gas lines 41 formed in the main body 31. The gas lines 41 diverge from a main gas line 42 that is connected to the gas source 35. The gas jet holes 33 deliver gas from the gas source 35 to introduce gas above the main body 31. The gas source 35 may be provided outside the chamber 10 and a valve (not shown) or a gas flow control unit (not shown) may be further provided. Further, the main body 31 may be connected to a driving unit 37. The driving unit 37 is capable of moving the main body 31 up and down and is capable of rotating the main body 31. The driving unit 37 may also be provided outside the chamber 10. At least a portion of the slope 39a of the subsidiary body 39 is disposed higher than the upper side of the main body 31, where the substrate 90 is placed, surrounding the side of the main body 31, and the slope 39a of the subsidiary body 39 declines towards the upper side of the main body 31. The subsidiary body 39 may be disposed around only predetermined portions of the side of the main body 31. Further, when plasma is generated inside the chamber 10, the subsidiary body 39 surrounding the side of the main body 31 may function as a focus ring that collects the plasma within the surrounded area. The subsidiary body 39 may be made of an insulating material or ceramic, such as Al₂O₃. The substrate support 30 may function as a lower electrode with respect to the upper electrode 20. The substrate support 30 may include a static electric chuck that attracts a substrate by using static electric force generated by power applied to an electrode provided in the static electric chuck.

The substrate 90 may be a wafer of semiconductor material on which semiconductor devices are to be formed, or a substrate on which flat panel display elements are to be formed, flat panel display elements such as thin film transistor substrates or color filter substrates. In particular, when the substrate 90 is a substrate for a flat panel display element, it may be a large area glass substrate. Plasma treatment is applied to the substrate 90 after the substrate 90 is inserted into the chamber 10 and then placed on the substrate support 30. The plasma treatment may be etching, physical or chemical deposition, or ion implantation or surface modification.

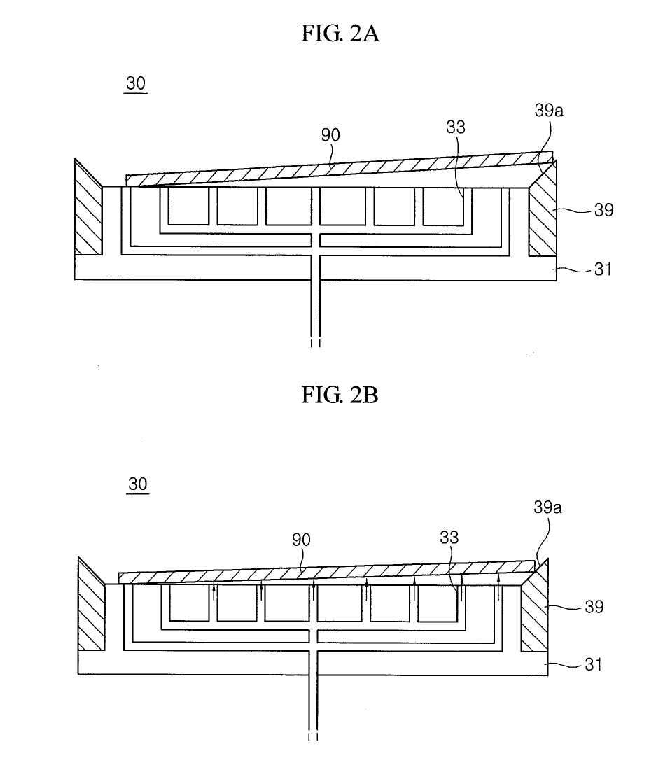

FIGS. 2A to 2C are schematic cross-sectional views sequentially illustrating a method of aligning a substrate according to an embodiment of the invention.

As shown in FIG. 2A, when the substrate 90 is placed on the main body 31 of the substrate support 30, the substrate 90 may be placed, not at the exact position desired, nor even within a predetermined distance from the exact position that is within an acceptable tolerance, the misplacement being due to, for example, retrogradation or deformation of a driving part of a substrate transporting unit (not shown). The exact position for the placement the substrate 90 on the substrate support 30 is the position where the upper side of the main body 31 of the substrate support 30 is covered by the substrate 90. Accordingly, the upper side of the main body 31 of the substrate support 30 may have an area corresponding to the area of the substrate 90. Therefore, when the substrate 90 is placed at a distance from the exact position, a portion of the substrate 90 is placed not on the upper side of the main body 31, but on the subsidiary body 39 surrounding the side of the main body 31, specifically, on the slope 39a of the subsidiary body 39. The slope 39a may be formed integrally with or separately from the subsidiary body 39 and is inclined to the upper side of the main body 31 where the substrate 90 is placed. Since the slope 39a of the subsidiary body 39 slopes downward toward the upper side of the main body 31, the subsidiary body 39 protrudes upwards from the upper side of the main body 31. That is, the upper end of the slope 39a is higher than the upper side of the main body 31. On the other hand, the lower end of the slope 39a may be higher or lower than the upper side of the main body 31, or may be disposed at the same height as the upper side of the main body 31. The angle of the slope 39a relative to the upper side of the main body 31 is not specified, but may be 45° or more.

Subsequently, as shown in FIG. 2B, under the influence of gravity, the substrate 90 with a portion placed on the slope 39a of the subsidiary body 39 slides along the slope 39a. Further, gas is ejected from the gas jet holes 33 of the main body 31 towards the lower surface of the substrate 90, i.e. the surface contacting the main body 31. The gas ejected from the gas jet holes 33 reduces the friction force between the substrate 90 and the main body 31 such that the substrate 90 smoothly slides down the slope 39a. The ejected gas may be gas that does not affect the process subsequently performed in processing the substrate 90. Inert gas, such as helium gas, may be exemplified as the above-mentioned gas. Further, the gas ejected from the gas jet holes 33 may be used in the subsequent process. Since the slope 39a declines to the upper side of the main body 31, the substrate 90 with a portion on the slope 39a of the subsidiary body 39 becomes correctly aligned on the main body 31 while gravity enables the portion of the substrate 90 on the slope 39a to smoothly slide down to the upper side of the main body 31. The substrate 90 floats above the main body 31 in spite of its weight when gas ejected from the gas holes 33 at a predetermined ejection pressure applies enough pressure to the underside of the substrate to overcome the force of gravity exerted per unit area of the substrate 90. The gas may be ejected from the gas jet holes 33 after the substrate 90 is placed, but may be ejected concurrently with or before placing the substrate 90 on the substrate support 30.

As described above, after sliding along the slope 39a, the substrate 90 arrives at the exact position on the upper side of the main body 31, as shown in FIG. 2C.

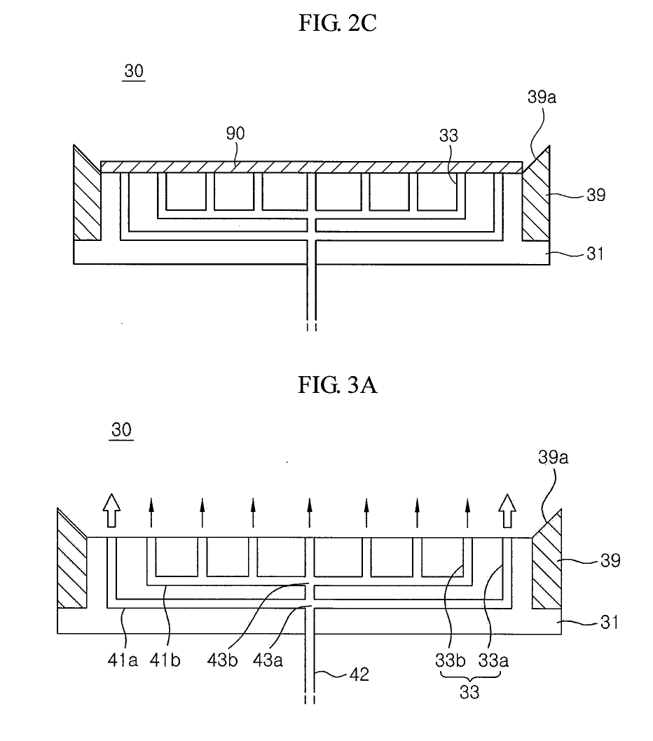

FIGS. 3A and 3B are views showing a first modification of a substrate support according to an embodiment and another example of the first modification.

Referring to FIG. 3A, a substrate support 30 has a plurality of gas jet holes 33 formed in a main body 31. The gas jet holes 33 include outer gas jet holes 33a and inner jet holes 33b. The gas ejection pressure at the outer gas jet hole 33a at the side of the main body 31 may be larger than that of the inner gas jet hole 33b at the center portion of the main body 31. According to this configuration, the gas ejection pressure is gradually decreased from the side of the main body 31, i.e. the edge of the main body 31 to the center portion thereof, or the gas ejection pressure of the outer gas jet hole 33a at the edge may be larger than the others. It is possible to more smoothly slide the substrate 90 along the slope 39a to the exact position as shown in FIG. 2B, by increasing the gas ejection pressure of the outer gas jet hole 33a. While a portion of the substrate 90 that is placed on the slope 39a is more spaced apart from the main body 31 than the other side of the substrate 90 which rests on the upper side of the substrate support 31, such that a larger force may be required to slide the portion of the substrate 90 smoothly. That is, the gas ejection pressure is more dispersed at the portion of the substrate 90 more spaced apart from the main body 31 as compared with the other side, such that the higher gas ejection pressure may be required to appropriately float the substrate 90. Further, because the gas ejected at the edge of the main body 31 is more easily dispersed from the main body 31 as compared with the center portion, the higher gas ejection pressure is required at the outer gas jet hole 33a. Therefore, with the configuration shown in FIG. 3A, it is possible to slide the substrate 90 smoothly by increasing the gas ejection pressure at the edge of the main body 31. The gas jet holes 33 and the gas lines connected to the gas jet holes may be arranged to achieve the above difference in gas ejection pressure. That is, it is possible to increase the gas ejection pressure at the outer gas jet hole 33a relative to the inner gas jet hole 33b by forming the main body so that the gas lines 41a for the outer gas jet holes 33a at the edge of the main body 31 diverge from a main gas line 42 at a first junction 43a that is close to the gas source 35 (see FIG. 1) and the gas lines 41b for the inner gas jet holes 33b at the center portion of the main body 31 diverge from the main gas line 42 at a second junction 43b that is downstream from the first junction 43a where the gas lines 41a for the outer gas jet holes 33a diverge.

However, the invention is not limited thereto and other configurations are possible. For example, it may be possible to make gas ejection pressures different by providing an individual flow feeder or further providing the gas source 35 for each of the gas jet holes 33. Further, controllers that separately control the gas supply for the outer gas jet holes 33a and the inner gas jet holes 33b may be provided, or as shown in FIG. 3B, a first main gas line 42a for supplying gas to the outer gas jet holes 33a, and a second main gas line 42b for supplying gas to the inner gas jet holes 33b may be separately provided.

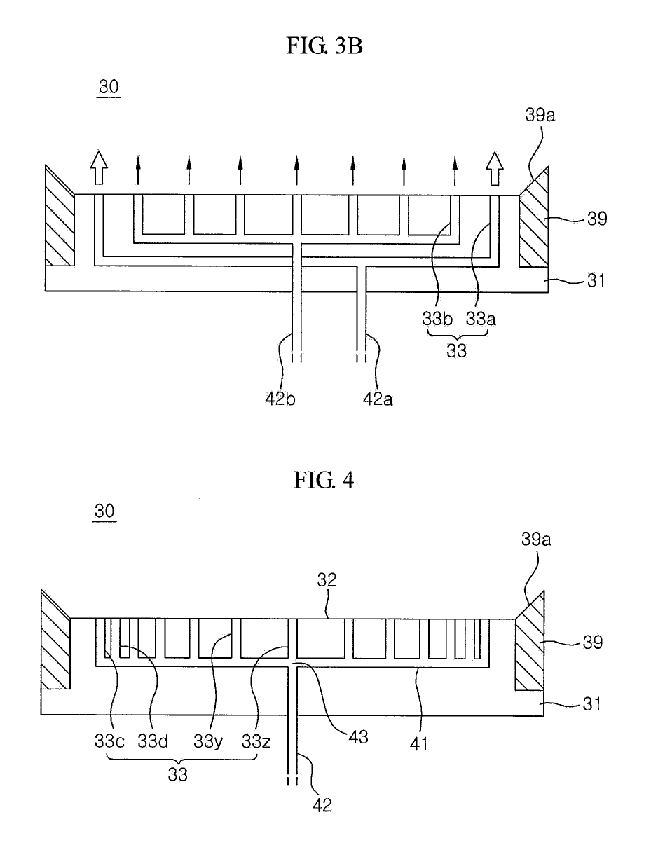

FIG. 4 is a view showing a second modification of a substrate support according to an embodiment of the invention.

Referring to FIG. 4, a substrate support 30 has a plurality of gas jet holes 33 formed in the upper side of a main body 31 and the distance between gas jet holes 33c and 33d of the gas jet holes 33 formed at the side of the main body 31 may be smaller than the distance between gas jet holes 33y and 33z formed at the center portion of the main body 31. In this configuration, it may be possible to gradually increase the distance between the gas jet holes 33 from the side of the main body 31, i.e. the edge of the main body 31 to the center portion, or decrease only the distance between the gas jet holes 33c and 33d at the edge. Further, the gas lines 41 for the gas jet holes 33 (33a, 33b, 33y, 33z) may diverge from the main gas line 42 which carries gas from the gas source 35 (see FIG. 1) at one junction 43. According to this configuration, more gas per unit area of the upper side 32 of the main body 31 may be ejected at the edge than at the center portion of the main body 31. While a portion of the substrate 90 is placed on a slope 39a, the portion on the slope 39a is more spaced apart from the main body as compared with the other side of the substrate 90, such that the substrate 90 may smoothly slide when more gas is ejected at the edge than at the center portion of the main body 31.

Further, the gas lines for the gas holes 33 may diverge at different positions along the main gas line 42 as shown in FIG. 3A or the gas lines may diverge from two main gas lines as shown in FIG. 3B, so that gas may be ejected at different ejection pressures.

Further, referring to FIG. 4, more gas jet holes 33 per unit area of the upper side 32 may be formed at the side of main body 31 than at the center portion. In this configuration, the numbers of the gas jet holes 33 per unit area may be gradually decreased from the side of the main body 31, that is, the edge of the main body 31 to the center portion of the main body 31, or the number of the gas jet holes 33 per unit area at the edge may be larger than the number of gas jets per unit area at the center portion. Further, a main gas line 42 for the gas jet holes 33 may extend from the gas source 35 (see FIG. 1) and gas lines 41 may diverge from one junction 43 in the main body 31. According to this configuration, more gas is ejected per unit area at the edge than at the center portion of the main body 31 and a portion of the substrate 90 on a slope 39a is relatively more spaced apart from the main body 31 than the other side of the substrate 90; therefore, a larger amount of gas is ejected at the edge than the center portion of the main body 31 by the larger number of gas jet holes 33 per unit area at the edge, such that the substrate 90 smoothly slides. The gas jet holes 33 may be supplied by gas lines that diverge from different points, and as in the first modification shown in FIGS. 3A and 3B, the gas jet holes 33 may eject gas at different pressures.

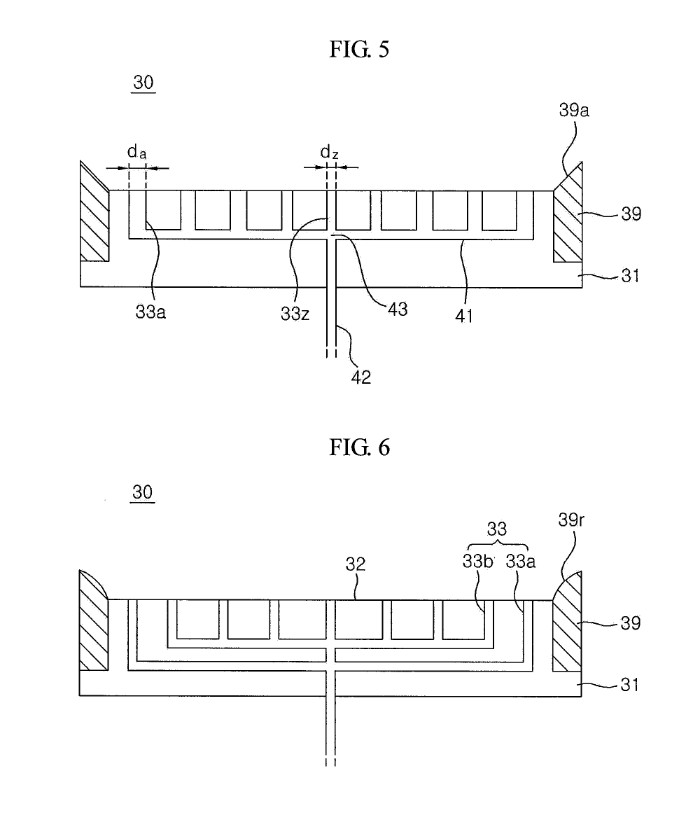

FIG. 5 is a view showing a third modification of a substrate support according to an embodiment of the invention.

Referring to FIG. 5, a substrate support 30 includes a main body 31 having a plurality of gas jet holes 33 and the diameter dₐ of a gas jet hole 33a formed at the side of the main body 31 may be larger than the diameter d_{z} of a gas jet hole 33z formed at the center portion of the main body 31. According to this configuration, the diameter of the gas jet holes 33 may be gradually decreased from the side of the main body 31, that is, the edge of the main body 31 to the center portion of the main body 31, or the gas jet holes 33a at the edge may have a larger diameter than the others. Further, gas lines 41 for the gas jet holes 33 (33a, 33z) may diverge from a junction 43 on a main gas line 42 that extends from the gas source 35 (see FIG. 1) and thus diverge from one point in the main body 31. Accordingly, more gas is ejected per unit area at the edge than the center portion of the main body 31. A portion of the substrate 90 on a slope 39a is relatively more spaced apart from the main body 31 than is the other side of the substrate; therefore, a larger amount of gas is ejected at the edge of the main body 31 than at the center portion of the main body 31, such that the substrate 90 smoothly slides. The gas lines supplying the gas jet holes 33 may diverge from different points, as in the first modification shown in FIGS. 3A and 3B. Thus the gas jet holes 33 may eject gas at different pressures, and as in the second modification shown in FIG. 4, the gas jet holes 33 may be arranged at different distances or in different numbers per unit area.

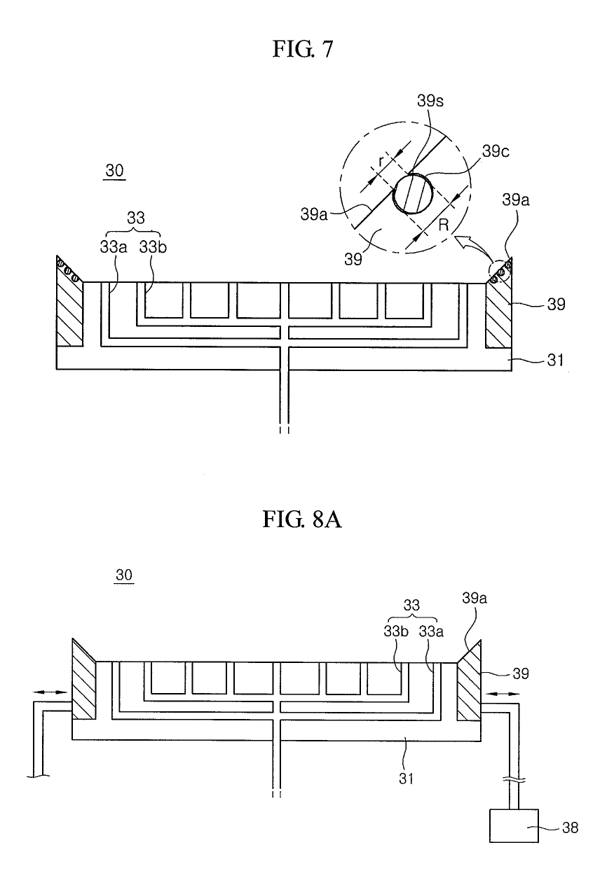

FIG. 6 is a view showing a fourth modification of a substrate support according to an embodiment of the invention.

Referring to FIG. 6, a substrate support 30 includes a main body 31 having a plurality of gas jet holes 33 and a subsidiary body 39 surrounding the side of the main body 31 and having a slope 39r declining to the upper side of the main body 31. The slope 39r of the subsidiary body 39 may be curved. According to this configuration, when a portion of the substrate 90 is placed on the slope 39r, the portion of the substrate 90 on the slope 39r may more smoothly slide along the slope 39r to the upper side of the main body 31. The closer to the upper side 32 of the main body 31, the more the angle between of the slope 39r and the upper side 32 of the main body 31 increases, such that the portion of the substrate 90 on the slope 39r can easily slide to the upper side of the main body 31. The curvature of the slope 39r is not limited to a specific value, but may be set such that a virtual line connecting the cross point of the slope 39r and the upper side of the main body 31 with the opposite end of the slope 39r to the cross point makes an angle of 45° or more. The fourth modification described with reference to FIG. 6 includes the same configuration of gas jet holes 33 as in the first modification shown in FIGS. 3A and 3B, but may have the configuration of the second modification or the third modification.

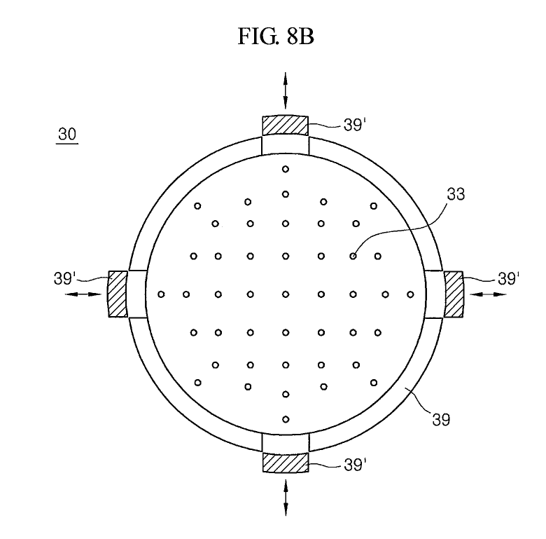

FIG. 7 is a view showing a fifth modification of a substrate support according to an embodiment of the invention.

Referring to FIG. 7, a substrate support 30 includes a main body 31 having a plurality of gas jet holes 33 and a subsidiary body 39 surrounding the side of the main body 31 and having a slope 39a declining to the upper side of the main body 31. A sliding portion may be formed at the slope 39a of the subsidiary body 39. The sliding portion is provided to allow a portion of the substrate 90 placed on the slope 39a to more smoothly slide to the upper side of the main body 31 and includes grooves 39c formed on the slope 39a and rigid balls 39s inserted in the grooves 39c. The rigid ball 39s has substantially spherical shape and at least one or more balls are provided in the grooves at the slope 39a such that they can rotate in the grooves 39c. Accordingly, when a portion of the substrate 90 is placed on the slope 39a, the rigid balls 39s rotate to allow the substrate 90 to more smoothly slide. Further, the rigid ball 39s may have a larger diameter R than the diameter r of the inlet of the groove 39c such that it is not readily removable from the groove 39c (i.e. r<R). The rigid ball 39s may be made of the same material as the subsidiary body 39 or a different material that does not affect chemically or physically the substrate during processing of the substrate. Further, the rigid ball 39s may be made of a soft or rigid material, or another material that is scarcely worn by the rotation in the groove 39c. Furthermore, the rigid ball 39s rotates while directly being in contact with the substrate 90, such that it is preferable to use a material that does no damage to the substrate 90. When the rigid ball 39s is made of a soft material, it may be press-fitted into the groove 39c. When the rigid ball 39s is made of a rigid material, the slope 39a may be separable. That is, the slope 39a may be separable such that the groove 39c is divided into two equal parts, and while the slope 39a is separated, the rigid ball 39s is inserted into one part of the groove 39c, and then the two parts of the slope 39a are combined to complete the sliding portion. This configuration of the rigid ball 39s is not limited to the above and may be another rotatable configuration. For example, a predetermined recess may be formed on the slope 39a, predetermined holes may be formed in the recess, the rigid ball 39s may have a rotational shaft that has a length larger than the diameter of the rigid ball 39s and passes through the center of the rigid ball 39s, and the rigid ball 39s may rotate about the rotational shaft with both ends inserted in the holes. Accordingly, when a portion of the substrate 90 is placed on the slope 39a, the substrate 90 with the portion on the slope 39a more smoothly sides along the slope 39a to the upper side of the main body 31 by rotation of the rigid balls 39s. The diameter R of the rigid ball 39s is not limited and the rigid ball 39s may protrude at a predetermined distance from the groove 39c of the slope 39a. The fifth modification described with reference to FIG. 7 includes the same configuration of gas jet holes 33 as in the first modification shown in FIGS. 3A and 3B, but may have the configuration of the second to the fourth modifications.

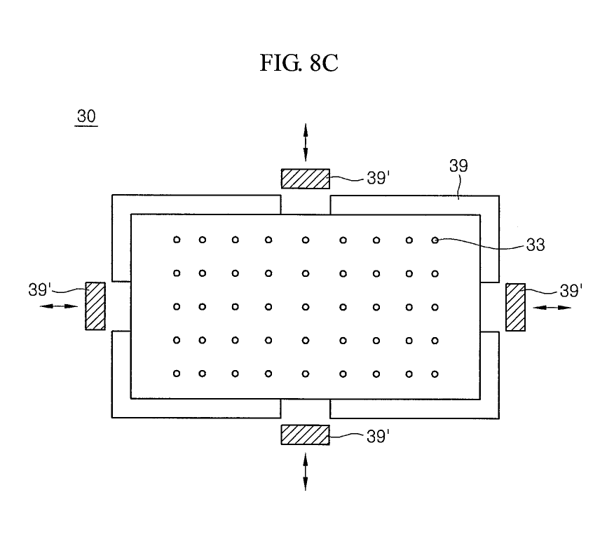

FIG. 8A is a view showing a sixth modification of a substrate support according to an embodiment of the invention, FIG. 8B is a plan view of the substrate support shown in FIG. 8A, which is formed for a circular substrate, and FIG. 8C is a plan view of the substrate support shown in FIG. 8A, which is formed for a rectangular substrate.

Referring to FIG. 8A, a substrate support 30 includes a main body 31 having a plurality of gas jet holes 33 and a subsidiary body 39 surrounding the side of the main body 31 and having a slope 39a declining to the upper side of the main body 31, and the subsidiary body 39 is movable in the side direction (indicated by the double headed arrows) of the main body 31. According to this configuration, the subsidiary body 39 may be driven by a driving unit 38. The movable subsidiary body 39 may be formed such that the entire subsidiary body 39 surrounding the side of the main body 31 is movable or only a part of the subsidiary body 39 is movable. That is, as shown in FIGS. 8B and 8C, each of two pairs of parts 39′ facing each other of the subsidiary body 39 may move in the side direction of the main body 31. FIG. 8B shows a substrate support for a circular substrate, such as a wafer for a semiconductor element, and FIG. 8C shows a substrate support for a rectangular substrate, such as a wide glass substrate for a flat panel display element. The part 39′ of the subsidiary body may be driven manually or automatically by the driving unit 38. Each of the parts 39′ of the subsidiary body may be separately driven or all of them may be simultaneously driven. Therefore, when a portion of the substrate 90 is placed out of the exact position on the main body 31, gas is ejected through the gas jet holes 33 and the subsidiary body 39 or the parts 39′ of the subsidiary body is moved to the main body 31 by the driving unit 38, such that the substrate 90 is placed to the exact position desired on the main body 31. According to this configuration, after the substrate 90 is placed on the main body 31 while the parts 39′ of the subsidiary body are spaced apart at a predetermined distance from the main body 31, as gas is ejected through the gas jet holes 33 and the parts 39′ of the subsidiary body 39 are moved to the main body 31 by the driving unit 38, the substrate 90 is moved to the exact position on the main body 31. That is, while the substrate 90 is placed, the parts 39′ of the subsidiary body 39 are spaced apart from the main body 31 and then the parts 39′ of the subsidiary body 39 move to the main body 31 just before start of processing the substrate, such that the substrate 90 is aligned. The sixth modification described with reference to FIGS. 8A to 8C includes the same configuration of gas jet holes 33 as in the first modification shown in FIGS. 3A and 3B, but as in the second modification shown in FIG. 4, the gas jet holes 33 may be arranged at different distances or in different numbers per unit area, or as in the third modification shown in FIG. 5, the gas jet holes 33 may have different diameters. Further, as in the fourth modification shown in FIG. 6, the curved slope 39r may be provided, or as in the fifth embodiment shown in FIG. 7, a sliding portion that allows the substrate 90 to smoothly slide may be provided.

After the substrate 90 is placed at the exact position on the main body 31 of the substrate support 30 as described above, processing using plasma is applied. Using the substrate supports 30 described according to the embodiments of the invention, it is possible to rapidly place the substrate 90 to the exact position even though the substrate 90 is placed out of a predetermined region of the main body 31. Further, by placing the substrate 90 to the exact position, it is possible to prevent arc discharge that is generated due to partial exposure of the main body 31 in the subsequent processing using plasma. Furthermore, since the arc discharge is prevented, it is possible to increase yield of the substrate 90 in the treatment process and secure the reliability of the processed substrate 90. In particular, when a wide substrate 90 for a wide flat panel display element is treated, because the substrate 90 is rapidly aligned to the exact position, it is possible to reduce processing time and stably perform processing using plasma, such as etching or depositing.

Although the present invention has been described in connection with the exemplary embodiments of the present invention, it will be apparent to those skilled in the art that various modifications and changes may be made thereto without departing from the scope and spirit of the invention.

For example, although a plasma processing apparatus is exemplified as a substrate processing apparatus herein, the invention may also be applied to other configurations within the aspects of the invention.

Further, although a wafer and a glass substrate are exemplified as a substrate in the detailed description and figures of the invention, the invention may also be applied to other substrates within the scope of the invention.

What is claimed is:

1. A substrate support comprising:
a main body on which a substrate is placed; and
a subsidiary body disposed around the side of the main body and having a slope declining from a position above the main body to the upper side of the main body.

2. The substrate support of claim 1, wherein a plurality of gas jet holes is formed through the upper side of the main body, and
ejection pressure of the gas jet holes at the edge of the upper side of the main body is larger than the ejection pressure of the gas jet holes at the center portion of the upper side of the main body.

3. The substrate support of claim 1, wherein a plurality of gas jet holes is formed through the upper side of the main body, and
the amount of ejection of the gas jet holes at the edge of the main body is larger than that of the center portion of the main body.

4. The substrate support of claim 3, wherein the distance between the gas jet holes at the edge of the main body is smaller than that of the center portion of the main body.

5. The substrate support of claim 3, wherein the diameter of the gas jet holes at the edge of the main body is larger than that of the center portion of the main body.

6. The substrate support of claim 3, wherein the number of the gas jet holes at the edge of the main body is larger than that of the center portion of the main body.

7. The substrate support of claim 1, wherein a sliding portion is formed on the slope.

8. The substrate support of claim 7, wherein the sliding portion includes grooves formed on the slope and rigid balls inserted in the grooves.

9. The substrate support of claim 8, wherein the diameter of the inlet of the groove is smaller than the diameter of the rigid ball.

10. The substrate support of claim 1, wherein at least a part of the subsidiary body is movable away from or close to the side of the main body.

11. The substrate support of claim 1, wherein the subsidiary body is made of ceramic.

12. The substrate support of claim 1, wherein the slope is curved.

13. The substrate support of claim 12, wherein the closer to the main body, the more the curvature of the slope increases.

14. A substrate processing apparatus comprising:
a chamber into which a substrate is inserted; and
a substrate support that is provided in the chamber and includes a main body on which the substrate is placed and a subsidiary body disposed around the side of the main body and having a slope declining from a position above the main body to the upper side of the main body.

15. The apparatus of claim 14, further comprising a plasma generator that generates plasma inside the chamber.

16. The apparatus of claim 14, wherein the substrate is a glass substrate or a semiconductor wafer.

17. A method of aligning a substrate comprising:
moving a subsidiary body away from a main body having a plurality of gas jet holes, the subsidiary body being disposed around the side of the main body and having a slope declining from a position above the main body to the upper side of the main body;
placing a substrate onto the main body;
ejecting gas onto the substrate placed on the upper side of the main body through the gas jet holes; and
moving the subsidiary body to the side of the main body.

18. The method of claim 17, wherein in the ejecting of gas, gas ejection pressure at the edge of the main body is larger than gas ejection pressure at the center portion of the main body.

19. The method of claim 17, wherein in the ejecting of gas, the gas ejection pressure is larger than gravity per unit area exerted in the substrate.

20. The method of claim 17, wherein in the ejecting of gas, the amount of gas ejection at the edge of the main body is larger than the amount of gas ejection at the center portion of the main body.
